(19) United States
(12) Patent Application Publication
(10) Pub. No.: US 2017/0020021 A1
(43) Pub. Date: Jan. 19, 2017

(54) SERVER HOUSING

(71) Applicant: Wistron Corporation, New Taipei City (TW)

(72) Inventors: Zhong-Hui MAO, New Taipei City (TW); Zhi-Peng ZOU, New Taipei City (TW)

(21) Appl. No.: 14/876,688

(22) Filed: Oct. 6, 2015

(30) Foreign Application Priority Data
Jul. 15, 2015 (CN) 201510416690.3

(51) Int. Cl. H05K 7/14

(52) U.S. Cl. CPC H05K 7/1488

(57) ABSTRACT

A server housing includes a housing bottom plate including an engaging hole and a hidden tray device including a tray bottom plate, a switch body, and a handle member. The tray bottom plate includes a receiving opening, a guiding trough, a first surface, and a second surface opposite to the first surface. The receiving opening and guiding trough penetrate through the tray bottom plate. The second surface is near the housing bottom plate. The switch body fastened to the first surface includes an engaging portion. The engaging portion passes through the receiving opening and is in the engaging hole. The handle member includes a handle body, a guiding portion, and a pressing unit. The guiding portion is connected to the handle body and is disposed in the guiding trough. The handle body and the pressing unit are between the tray bottom plate and the housing bottom plate.

### CROSS-REFERENCES TO RELATED APPLICATIONS

This non-provisional application claims priority under 35 U.S.C. §119(a) on Patent Application No. 201510416690.3 filed in China, P.R.C. on Jul. 15, 2015, the entire contents of which are hereby incorporated by reference.

### BACKGROUND

Technical Field

The instant disclosure relates to a housing, and more particularly, to a server housing.

Related Art

Unlike a personal computer utilized for a single user operation, a server is utilized for handling operation requests from multiple users and processing a large amount of data interchange. Since the number of users of servers could be varied over time, the performance of servers about calculation and access capabilities can be adjustable and expanded in response to variable loading. Therefore, hardware of servers is not only needed to meet the requirement of performance, but is also needed to be expandable.

In order to improve the expandability of servers, a rack server has been provided. The rack server includes a housing, at least a tray, and at least a server module. The housing includes at least a slide rail disposed therein. The tray is slidably disposed on the slide rail. Each server module is disposed on each tray. The server module includes electronic components. The electronic components include a board, a hard drive, or a power supply. Multiple server modules can be inserted into the rack server via multiple slide rails; thereby the overall performance of the rack server can be increased. For example, the calculation capabilities, the storage space, or the source power can be increased. Under the circumstance that the rack server is needed to be maintained or adjusted, users can pull out the server module for further detection, maintenance, and replacement.

In order to conveniently push/pull the server module in/out, the server module generally includes a handle and an engaging lock both disposed on a side of the server module extending outside the housing. If the server module is needed to be inserted in the housing, users can push the server module in the housing along the side rail and then close the engaging lock to have the server module locked to the housing. If the server module is needed to be pulled out, users can open the engaging lock and then hook the handle to pull the server module out along the slide rail.

### SUMMARY

The aforementioned prior handle and engaging lock are both disposed outside the housing of the server. For the sake of convenient operation, the prior handle and engaging lock extend outside the housing; consequently, the server overall occupies more space. In addition, it is inconvenient that the handle and engaging lock have to be individually operated by users in order to push/pull the server module in/out and to have the server module engaged to or detached from the housing. To address the above issue, the instant disclosure provides a server housing which occupies less space and is more convenient in terms of operation.

According to an embodiment of the instant disclosure, the server housing comprises a housing bottom plate and a hidden tray device. The housing bottom plate comprises an engaging hole. The hidden tray device comprises a tray bottom plate, a switch body, and a handle member. The tray bottom plate comprises a receiving opening, at least a guiding trough, a first surface, and a second surface opposite to the first surface. The receiving opening and the guiding trough penetrate through the tray bottom plate from the first surface to the second surface. The second surface is near the housing bottom plate. The switch body comprises an engaging portion. One end of the switch body is fastened to the first surface of the tray bottom plate, and the engaging portion protrudes from the other end of the switch body. The engaging portion passes through the receiving opening and is in the engaging hole. The handle member comprises a handle body, at least a guiding portion, and a pressing unit. The guiding portion is connected to the handle body and is slidably disposed in the guiding trough of the tray bottom plate. The handle body and the pressing unit are between the tray bottom plate and the housing bottom plate. When the guiding portion slides in the guiding trough, the pressing unit is capable of pressing the engaging portion and having the engaging portion moved out of the engaging hole.

According to an embodiment of the instant disclosure, the number of the guiding trough is two, and the two guiding troughs are symmetrically disposed on two sides of the receiving opening. The number of the guiding portion is two, and the two guiding portions are symmetrically disposed on two sides of the handle body. Wherein the guiding portion comprises a guiding plate and a pressing plate. One end of the guiding plate is connected to the handle body, and the other end of the guiding plate is connected to the pressing plate. The guiding plate is in the guiding trough. The pressing plate is against the first surface of the tray bottom plate.

In addition, the guiding trough comprises a first trough section and a second trough section. The trough width of the first trough section is greater than that of the second trough section. The trough width of the second trough section is substantially equal to the thickness of the guiding plate.

According to an embodiment of the instant disclosure, the handle body further comprises a receiving trough. The receiving trough penetrates through the handle body and is parallel with the guiding trough. The engaging portion passes through the receiving trough. The pressing unit is at one end of the receiving trough.

According to an embodiment of the instant disclosure, the switch body further comprises a first plate body and a second plate body connected to the first plate body. The first plate body is fastened to the first surface of the tray bottom plate. The engaging portion is on the second plate body. The second plate body is biased toward the receiving opening. A side of the second plate body away from the first plate body is against the handle body.

In addition, the tray bottom plate further comprises two fastening posts protruding from the first surface of the tray bottom plate. The switch body further comprises two fastening holes penetrating through the first plate body. The two fastening posts respectively pass through the two fastening holes.

Moreover, the tray bottom plate further comprises a positioning post protruding from the first surface of the tray bottom plate. The switch body further comprises a positioning notch recessed from an edge of the first plate body away from the second plate body. The positioning post is engaged to the positioning notch.

According to an embodiment of the instant disclosure, the engaging portion comprises a steep face and a gradual face opposite to the steep face. The gradual face faces toward the pressing unit. The steep face is against an inner side of the engaging hole. The pressing unit is capable of being against the gradual face and pressing the engaging portion to have the engaging portion moved out of the engaging hole.

According to an embodiment of the instant disclosure, the handle body further comprises a convex structure, and the tray bottom plate further comprises a concave structure. The convex structure and the concave structure are contacted with each other for positioning.

According to an embodiment of the instant disclosure, the housing bottom plate further comprises a receiving notch recessed from an edge of the housing bottom plate. The handle member further comprises a pulling portion connected to the handle body. The pulling portion is opposite to the pressing unit and is near the second surface of the tray bottom plate. At least a part of the pulling portion extends to outside the receiving notch.

Concisely, the server housing of an embodiment of the instant disclosure occupies less space based on the design of the hidden tray device. Moreover, by means of the cooperation of the handle member, the switch body, and the tray bottom plate of an embodiment, the handle body can be hidden below the tray bottom plate when the engaging portion is in an engaged state. Further, the operation of pulling out the handle body can not only disengage the engaged state of the engaging portion, but can also pull the hidden tray device out simultaneously. As a result, the embodiment of the instant disclosure is more convenient in terms of operation.

The features of the instant disclosure will no doubt become understandable to those of ordinary skill in the art after reading the following detailed description of the preferred embodiment that is illustrated in the various figures and drawings.

### BRIEF DESCRIPTION OF THE DRAWINGS

FIG. 1 illustrates a perspective view of a server according to an embodiment of the instant disclosure;

FIG. 2 illustrates a perspective view of a server housing according to an embodiment of the instant disclosure;

FIG. 3 illustrates a partial perspective view of the server housing according to an embodiment of the instant disclosure;

FIG. 4 illustrates a partial exploded view of the server housing according to an embodiment of the instant disclosure;

FIG. 5 illustrates a partial perspective view of a housing bottom plate according to an embodiment of the instant disclosure;

FIG. 6 illustrates a partial perspective view of a tray portion of a hidden tray device according to an embodiment of the instant disclosure;

FIG. 7 illustrates a perspective view of a switch body of the hidden tray device according to an embodiment of the instant disclosure;

FIG. 8 illustrates a perspective view of a handle member of the hidden tray device according to an embodiment of the instant disclosure;

FIG. 9 illustrates a partial perspective view of an engaging portion of the hidden tray device in an engaged state according to an embodiment of the instant disclosure;

FIG. 10 illustrates a cross-sectional view taken alone the line 10-10 of FIG. 9; and

FIG. 11 illustrates a partial perspective view of the engaging portion of the hidden tray device in a disengaged state according to an embodiment of the instant disclosure.

### DETAILED DESCRIPTION

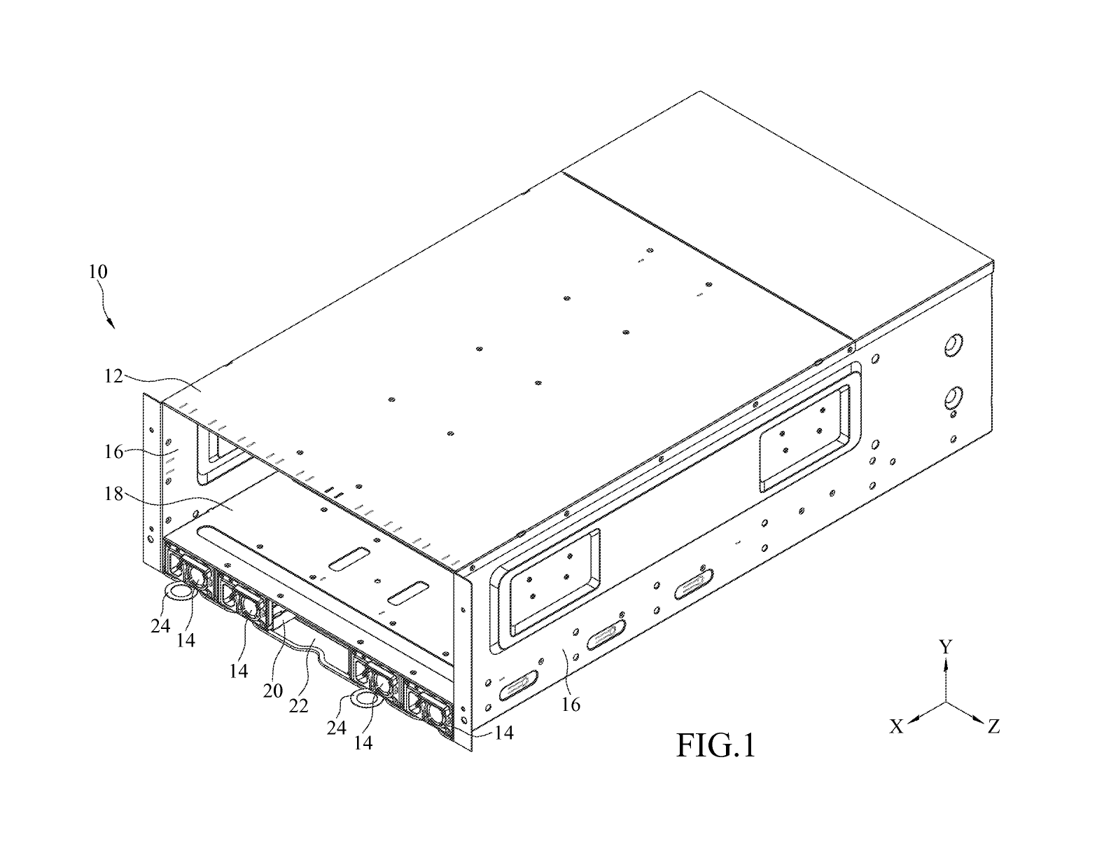

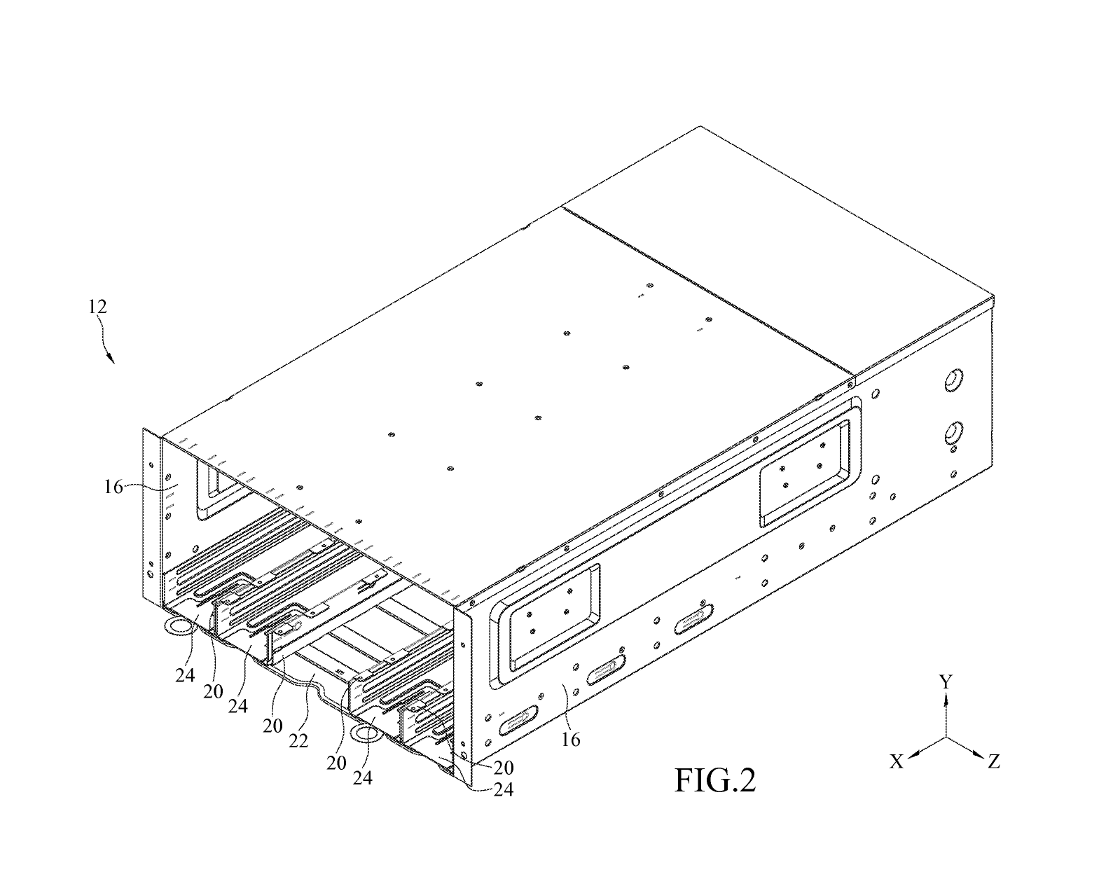

Referring to FIG. 1 and FIG. 2, FIG. 1 illustrates a perspective view of a server 10 according to an embodiment of the instant disclosure, and FIG. 2 illustrates a perspective view of a server housing 12 according to an embodiment of the instant disclosure. In the embodiment, the server 10 pertains to, but is not limited to, the type of rack servers. The server 10 comprises a server housing 12 and a plurality of server modules 14. The server housing 12 comprises two housing side plates 16, a housing middle plate 18, a plurality of housing separating plates 20, a housing bottom plate 22, and a plurality of hidden tray devices 24. In the embodiment, each server module 14 is respectively disposed on each hidden tray device 24. In other embodiments, the server can only comprise one server module, and the server housing can comprise only one corresponding hidden tray device.

The two housing side plates 16 are respectively disposed on two opposite sides of the housing bottom plate 22. The housing separating plates 20 are disposed on the housing bottom plate 22 and are perpendicularly to the housing bottom plate 22. The housing middle plate 18 covers above the housing separating plates 20. In the embodiment, as shown in FIG. 1 and FIG. 2, There are four housing separating plates 20 two of which are located inside and two of which are located outside (i.e., the outside housing separating plate 20 is closer to the housing side plate 16 than the inside housing separating plate 20). There is an accommodating space formed between the housing bottom plate 22, the one of the outside housing separating plates 20, the one of the housing side plates 16, and the housing middle plate 18, and there is another accommodating space formed between the housing bottom plate 22, the other one of the outside housing separating plates 20, the other one of the housing side plates 16, and the housing middle plate 18. Similarly, there is an accommodating space formed between the housing bottom plate 22, the one of the outside housing separating plates 20, the one of the inside housing separating plates 20, and the housing middle plate 18, and there is another accommodating space formed between the housing bottom plate 22, the other one of the outside housing separating plates 20, the other one of the inside housing separating plates 20, and the housing middle plate 18. Wherein, there are, but are not limited to, four accommodating spaces in the embodiment. Each of the accommodating spaces has a height along the Y direction, a width along the Z direction, and a depth along the X direction, respectively, corresponding to a height, a width, and a length of the assembly of the server module 14 and the hidden tray device 24. Each of the assemblies of the server module 14 and the hidden tray device 24 is slidably disposed in the accommodating space. Specifically, each of the assemblies of the server module 14 and the hidden tray device 24 is restricted and is unable to move along the positive and negative Y directions and the positive and negative Z directions; however, each of the assemblies of the server module 14 and the hidden tray device 24 is capable of moving along the positive and negative X directions. In other words, the server module 14 can be pulled, along the positive X direction, out of the server housing 12 via the hidden tray device 24 or can be pushed, along the negative X direction, in the server housing 12. The server module 14 comprises electronic components such as boards, memories, processors, hard drives, or power suppliers. In the embodiment, the server module 14 comprises, but is not limited to, a power supply.

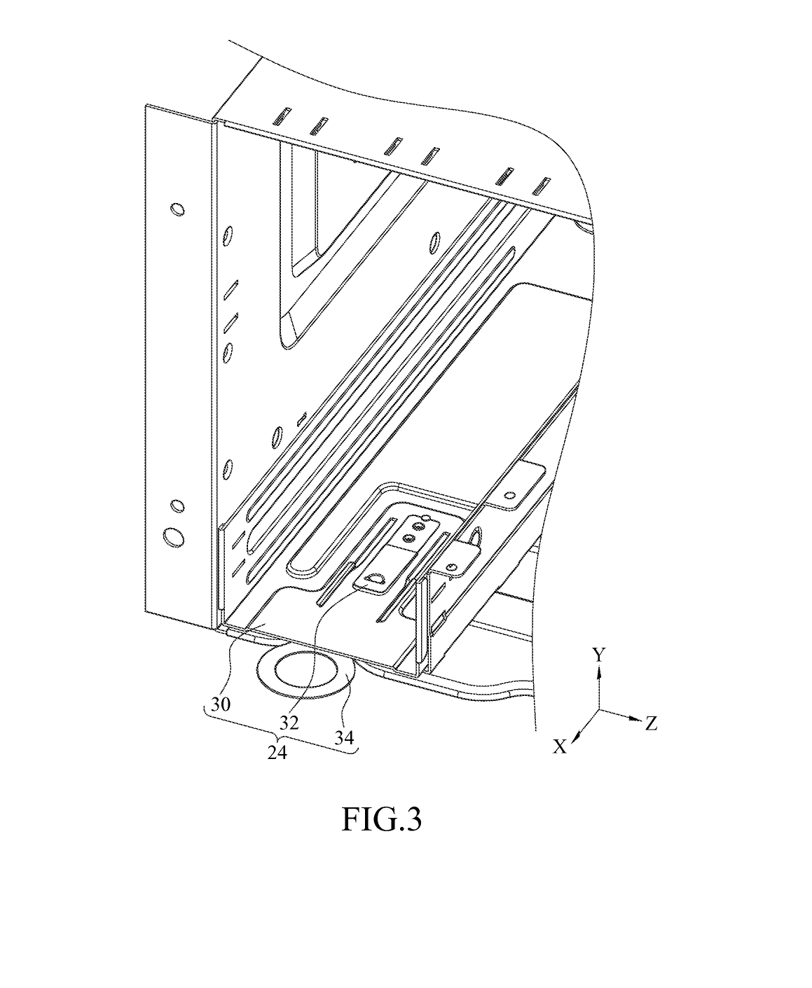

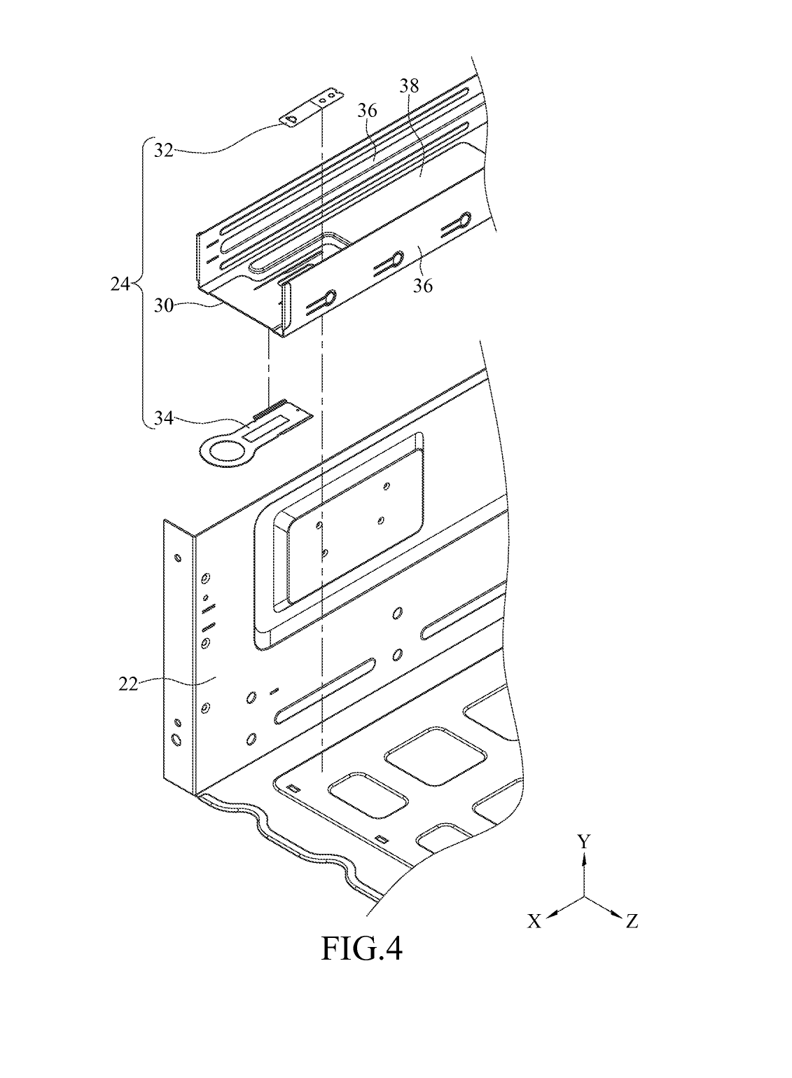

Referring to FIG. 3 and FIG. 4, FIG. 3 illustrates a partial perspective view of the server housing 12 according to an embodiment of the instant disclosure, and FIG. 4 illustrates a partial exploded view of the server housing 12 according to an embodiment of the instant disclosure. In the embodiment, the hidden tray device 24 comprises a tray portion 30, a switch body 32, and a handle member 34. The tray portion 30 comprises two tray side plates 36 and a tray bottom plate 38. The two tray side plates 36 are disposed on two opposite sides of the tray bottom plate 38 and are perpendicular to the tray bottom plate 38. The two tray side plates 36 are respectively against the adjacent housing side plate 16 and the adjacent housing separating plate 20 (or against the two adjacent housing separating plates 20 depending on which one of the accommodating spaces the hidden tray device 24 is located at); therefore, the tray portion 30 can slide along the positive and negative X direction between the adjacent housing side plate 16 and adjacent housing separating plate 20 (or between the two adjacent housing separating plates 20). The handle member 34 is sandwiched between the tray bottom plate 38 and the housing bottom plate 22. The switch body 32 is at a side of the tray bottom plate 38 opposite to the handle member 34.

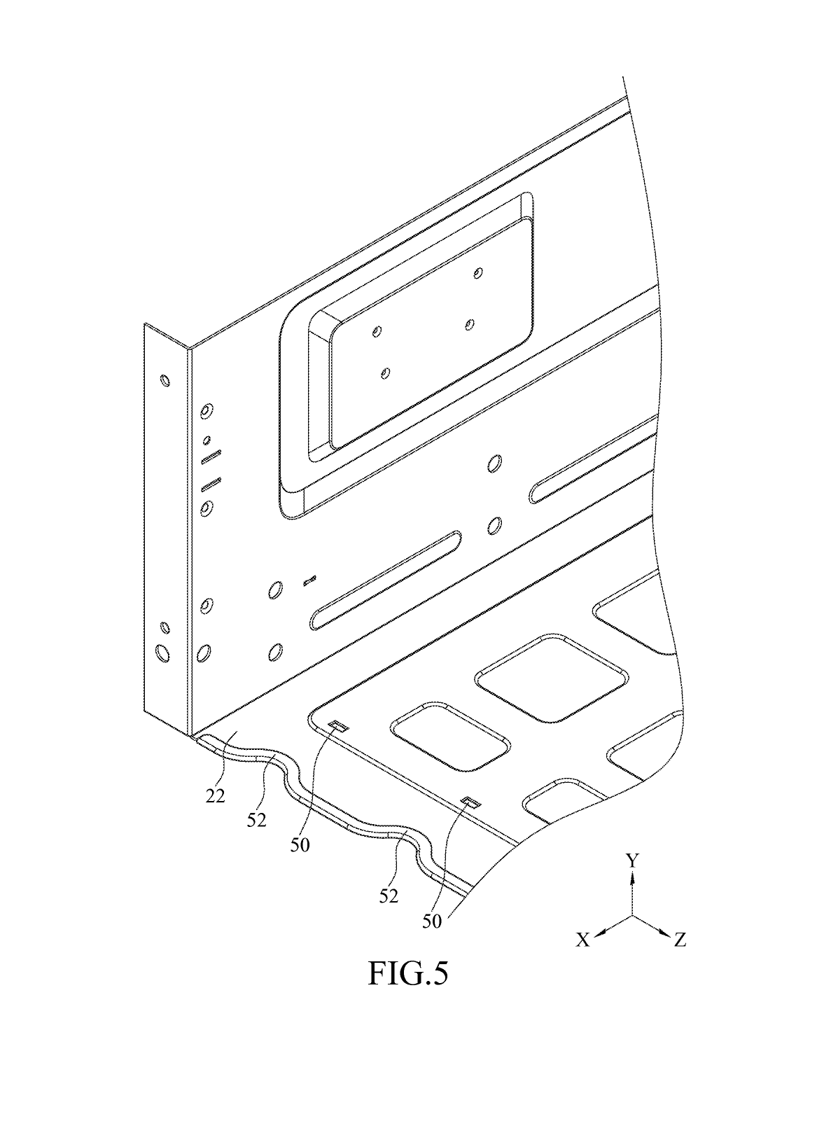

Referring to FIG. 5, FIG. 5 illustrates a partial perspective view of the housing bottom plate 22 according to an embodiment of the instant disclosure. In the embodiment, the housing bottom plate 22 comprises a plurality of engaging holes 50 and a plurality of receiving notches 52. Each engaging hole 50 penetrates through the housing bottom plate 22. Each receiving notch 52 is recessed from an edge of the housing bottom plate 22. Each engaging hole 50 is corresponding to each receiving notch 52. Each engaging hole 50 and each receiving notch 52 is corresponding to each hidden tray device 24.

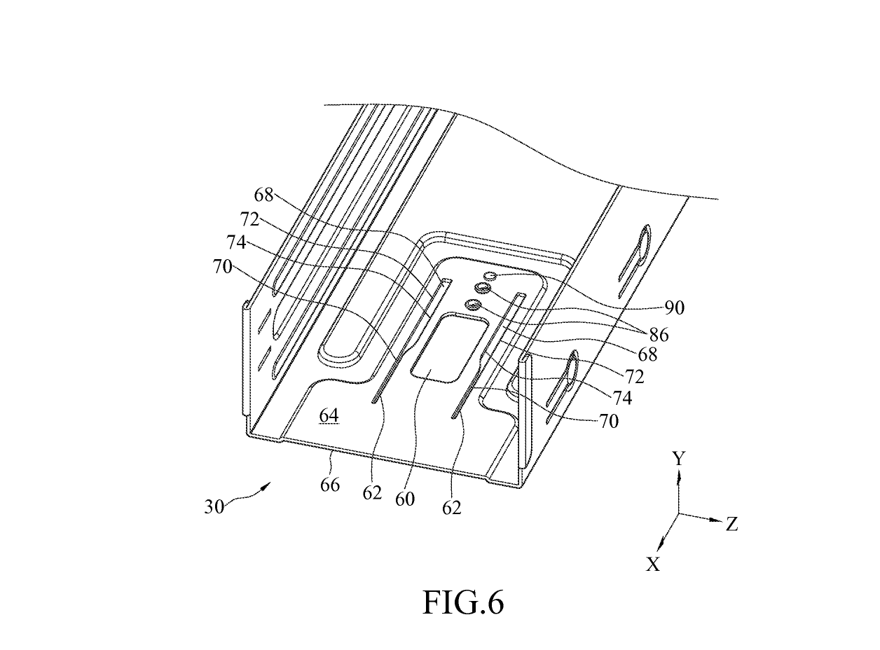

Referring to FIG. 6, FIG. 6 illustrates a partial perspective view of the tray portion 30 of the hidden tray device 24 according to an embodiment of the instant disclosure. In the embodiment, the tray bottom plate 38 comprises a receiving opening 60, a guiding trough 62, a first surface 64, and a second surface 66 opposite to the first surface 64. The receiving opening 60 and the guiding trough 62 penetrate through the tray bottom plate 38 from the first surface 64 to the second surface 66. As shown in FIG. 4, the second surface 66 is near the housing bottom plate 22. In the embodiment, the number of the guiding trough 62 is two, and the two guiding troughs 62 are symmetrically disposed on two sides of the receiving opening 60. The guiding trough 62 extends along the X direction. The guiding trough 62 comprises a first trough section 68 and a second trough section 70. The first trough section 68 and the second trough section 70 are aligned along the X direction. The guiding trough 62 has an outer side edge 72 and an inner side edge 74 opposite to the outer side edge 72. The outer side edge 72 is away from the receiving opening 60, and the inner side edge 74 is near the receiving opening 60. The outer side edges 72 of the first trough section 68 and the second trough section 70 are aligned along the X direction. The inner side edge 74 of the first trough section 68 extends toward the receiving opening 60, and thus is closer to the receiving opening 60 than the inner side edge 74 of the second trough section 70. Accordingly, a step (difference) is formed between the inner side edges 74 of the first trough section 68 and the second trough section 70. The trough width of the first trough section 68 is greater than that of the second trough section 70.

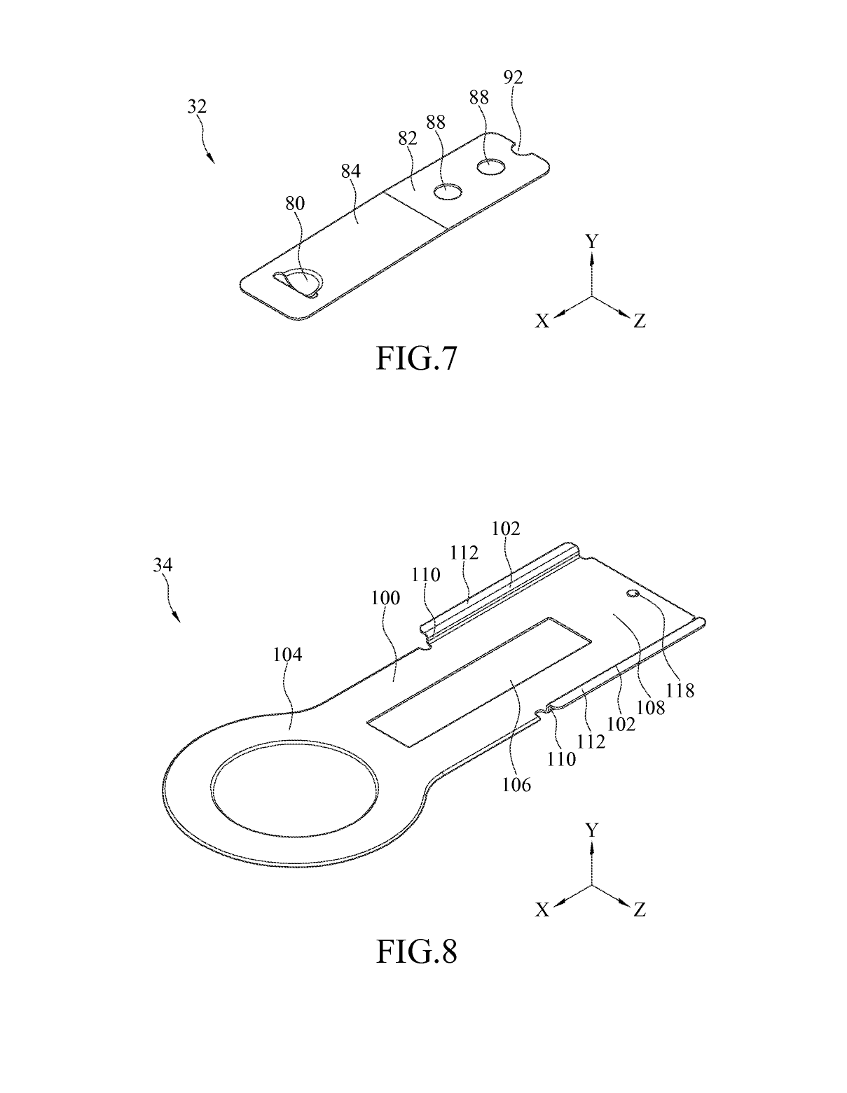

Referring to FIG. 7, FIG. 7 illustrates a perspective view of the switch body 32 of the hidden tray device 24 according to an embodiment of the instant disclosure. In the embodiment, the switch body 32 comprises an engaging portion 80. One end of the switch body 32 is fastened to the first surface 64 of the tray bottom plate 38, and the engaging portion 80 protrudes from the other end of the switch body 32. Specifically, the switch body 32 further comprises a first plate body 82 and a second plate body 84 connected to the first plate body 82. As shown in FIG. 3, FIG. 4, and FIG. 6, the first plate body 82 is fastened to the first surface 64 of the tray bottom plate 38. The second plate body 84 is slightly bent with respect to the first plate body 82. The engaging portion 80 is on the second plate body 84. In the embodiment, the formation of the engaging portion 80 is to have a predetermined position of the second plate body 84 broken in advance, and then to have the predetermined position recessed downwardly to form the engaging portion 80.

In the embodiment, as shown in FIG. 6, the tray bottom plate 38 further comprises two fastening posts 86. The two fastening posts 86 protrude from the first surface 64 of the tray bottom plate 38. The switch body 32 further comprises two fastening holes 88. The two fastening holes 88 penetrate through the first plate body 82. The two fastening posts 86 respectively pass through the two fastening holes 88. In the embodiment, the fastening post 86 and the fastening hole 88 are riveted together. In addition, the switch body 32 is non-rotatable with respect to the tray bottom plate 38 by two-point fixation (i.e., the two fastening posts 86 are respectively fastened to the two fastening holes 88). In other embodiments, the fastening post and the fastening hole can be welded together. Moreover, the tray bottom plate and the switch body can be fastened to each other by other means without the fastening post and the fastening hole. For example, an edge of one end of the switch body contacting the tray bottom plate can be welded to the tray bottom plate so that the switch body can be fastened to the tray bottom plate.

Moreover, in the embodiment, the tray bottom plate 38 further comprises a positioning post 90. The positioning post 90 protrudes from the first surface 64 of the tray bottom plate 38. The positioning post 90 and the two fastening posts 86 are, but are not limited to, aligned along the X direction. The switch body 32 further comprises a positioning notch 92. The positioning notch 92 is recessed from an edge of the first plate body 82 away from the second plate body 84. The positioning post 90 is engaged to the positioning notch 92. During the process of having the switch body 32 engaged to the tray bottom plate 38, the positioning notch 92 of the switch body 32 can be aligned with and then engaged to the positioning post 90 of the tray bottom plate 38 in advance. Based on the cooperation of the positioning post 90 and the positioning notch 92 utilized for positioning purpose, the two fastening holes 88 are aligned with the two fastening posts 86, and then the fastening posts 86 pass through the fastening holes 88. As a result, the switch body 32 is assembled to the tray bottom plate 38. Finally, the fastening post 86 is riveted to the fastening hole 88.

Referring to FIG. 8, FIG. 8 illustrates a perspective view of the handle member 34 of the hidden tray device 24 according to an embodiment of the instant disclosure. In the embodiment, the handle member 34 comprises a handle body 100, a guiding portion 102, a pulling portion 104, and a pressing unit 108. The guiding portion 102 and the pulling portion 104 are respectively connected to the handle body 100. As shown in FIG. 3, FIG. 4, and FIG. 6, the guiding portion 102 is slidably disposed in the guiding trough 62 of the tray bottom plate 38. The handle body 100 and the pressing unit 108 are sandwiched between the tray bottom plate 38 and the housing bottom plate 22. In the embodiment, the handle body 100 comprises a receiving trough 106. The receiving trough 106 penetrates through the handle body 100 and is parallel with the guiding trough 62. The pressing unit 108 is at one end of the receiving trough 106. The pulling portion 104 is opposite to the pressing unit 108. The pulling portion 104 is near the second surface 66 of the tray bottom plate 38, and the pulling portion 104 has an annular shape and is a flat structure. Users can hook the pulling portion 104 by fingers and then can pull the handle member 34 out. In the embodiment, the number of the guiding portion 102 is two, and the two guiding portions 102 are symmetrically disposed on two sides of the handle body 100. The guiding portion 102 comprises a guiding plate 110 and a pressing plate 112. One end of the guiding plate 110 is connected to the handle body 100, and the other end of the guiding plate 110 is connected to the pressing plate 112. The guiding plate 110 is in the guiding trough 62. The pressing plate 112 is against the first surface 64 of the tray bottom plate 38. The pressing plate 112 extends toward a direction away from the handle body 100. In another embodiment, there can be only one guiding trough disposed on a side of the receiving opening (e.g., being in front of the receiving opening along the X direction); consequently, there is only one guiding portion disposed on a place of the handle body (e.g., being on the middle place of the handle body and being perpendicularly to the handle body). In the embodiment, the trough width of the second trough section 70 is substantially equal to the thickness of the guiding plate 110, and the trough width of the first trough section 68 is substantially equal to or slightly less than the width of the pressing plate 112. However, the embodiments of the instant disclosure are not limited to the aforementioned example.

For example, the trough width of the first trough section can be greater than the width of the pressing plate in other embodiments. An interval between the two guiding plates 110 is substantially equal to that between the two outer side edges 72 of the two guiding troughs 62. The pressing plate 112 is against the first surface 64 and is at an outer periphery of the guiding trough 62 (i.e., a place near a side of the guiding trough 62 away from the receiving opening 60).

The design that the trough width of the first trough section 68 is greater than that of the second trough section 70 benefits two aspects: one is that the handle member 34 can be assembled to the tray bottom plate 38 more easily, and the other one is that the stability during the operation that the handle member 34 is forced by users to push/pull the tray bottom plate 38 in/out can be improved. The process of having the handle member 34 assembled to the tray bottom plate 38 is described below. Firstly the two sides of the handle body 100 are pressed to have the guiding portions 102 of the two sides of the handle body 100 been slightly close to each other. And the pressing plates 112 are aligned with the first trough sections 68 of the guiding troughs 62. Then the pressing plates 112 are moved to pass through the first trough sections 68 in a forward or an oblique direction. Next is to stop pressing the two sides of the handle body 100 when the pressing plates 112 pass through the first trough sections 68. Then the two guiding portions 102 return to the initial position. In the mean time, the guiding plates 110 are against the outer side edges 72 of the first trough sections 68, and the pressing plates 112 are against the first surface 64 of the tray bottom plate 38. As a result, the assembling process of the handle member 34 and the tray bottom plate 38 is accomplished. In addition, during the process of pulling the handle member 34 out of the tray bottom plate 38, the guiding plates 110 are going to enter the second trough sections 70 in advance. Since the trough width of the second trough section 70 is substantially equal to the thickness of the guiding plate 110, the two second trough sections 70 are beneficial for maintaining the relative position of the two guiding portions 102 so as to avoid the handle body 100 being warped and deformed by pulling force.

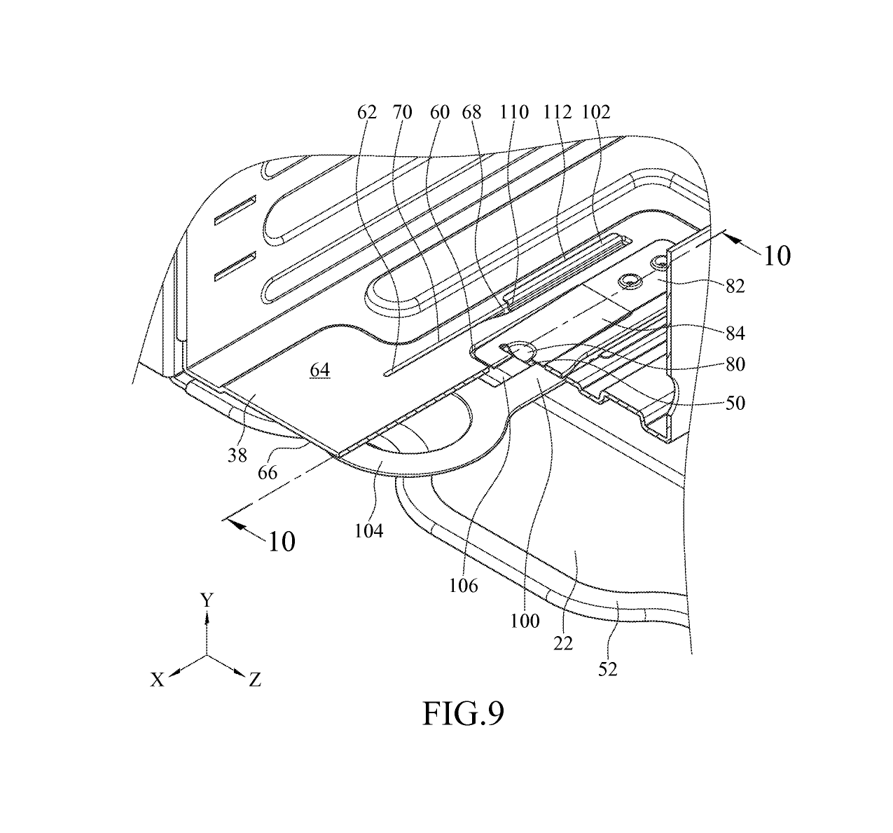

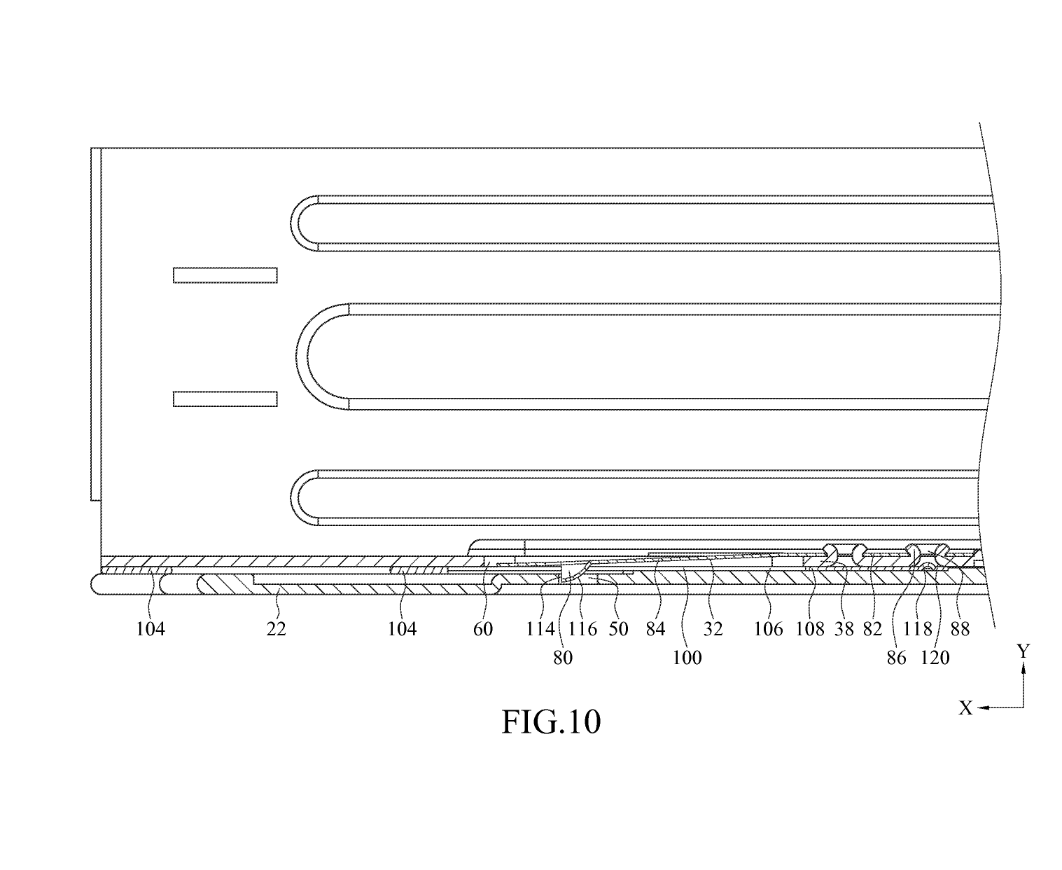

Referring to FIG. 9 and FIG. 10, FIG. 9 illustrates a partial perspective view of the engaging portion 80 of the hidden tray device 24 in an engaged state according to an embodiment of the instant disclosure, and FIG. 10 illustrates a cross-sectional view taken alone the line 10-10 of FIG. 9. In the embodiment, as shown in FIG. 10, the engaging portion 80 comprises a steep face 114 and a gradual face 116 opposite to the steep face 114. The gradual face 116 faces toward the pressing unit 108. The steep face 114 is against an inner side of the engaging hole 50. When the handle member 34 is moved to an end position along the negative X direction, the guiding plate 110 is in the first trough section 68. In the embodiment, the handle body 100 further comprises a convex structure 118, and the tray bottom plate 38 further comprises a concave structure 120. The convex structure 118 and the concave structure 120 are contacted with each other for positioning. When users need to push the handle member 34 to the end position along the negative X direction, the contact of the convex structure 118 and the concave structure 120 provides a positioning effect. When the engaging portion 80 is in the engaged state, the second plate body 84 is biased toward the receiving opening 60, and a side of the second plate body 84 away from the first plate body 82 is against the handle body 100; consequently, the engaging portion 80 passes through the receiving opening 60 and the receiving trough 106, and the engaging portion 80 is in the engaging hole 50. The steep face 114 of the engaging portion 80 is against the edge of the engaging hole 50; therefore, the engaging portion 80 cannot be moved along the X direction. Accordingly, all of the switch body 32, the tray portion 30, the hidden tray device 24, and the server module 14 cannot be moved along the X direction. In other words, the hidden tray device 24 and the server module 14 are in the engaged state and cannot be pulled out.

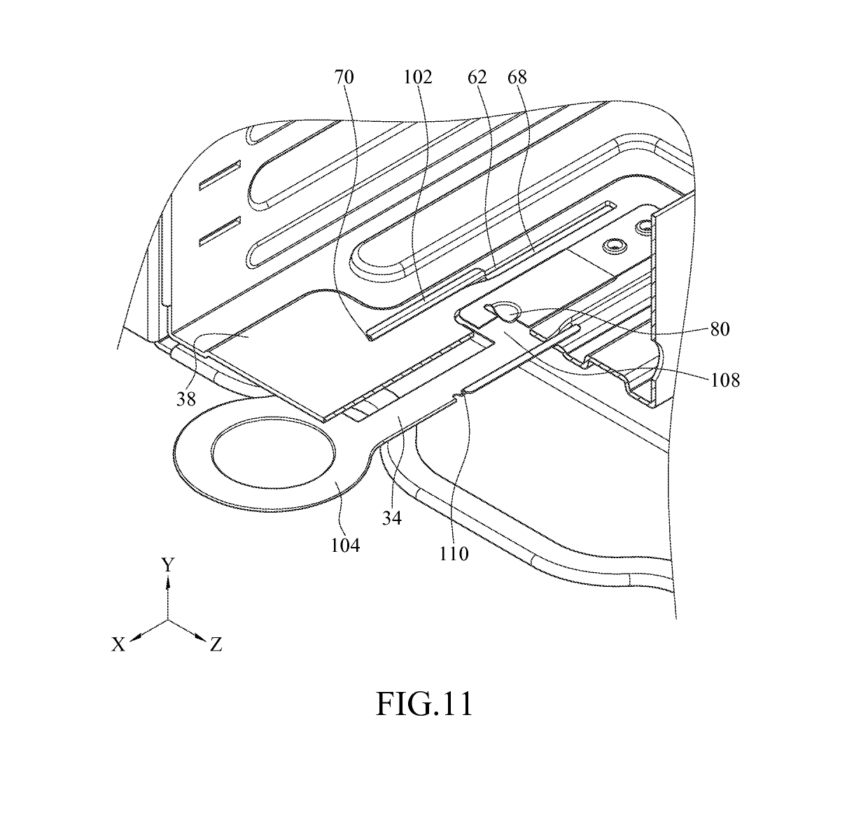

Referring to FIG. 10 and FIG. 11, FIG. 11 illustrates a partial perspective view of the engaging portion 80 of the hidden tray device 24 in a disengaged state according to an embodiment of the instant disclosure. When users need to disengage the engaged state of the engaging portion 80, users can pull the pulling portion 104 out along the X direction to have the handle member 34 moved along the X direction. In the process, the guiding portion 102 slides in the guiding trough 62. When the pressing unit 108 contacts the engaging portion 80, the pressing unit 108 is against the gradual face 116 of the engaging portion 80 and presses the engaging portion 80 (i.e., having the engaging portion 80 moved along the Y direction). When the front of the pressing unit 108 passes the engaging portion 80, the engaging portion 80 moves out of the engaging hole 50 completely because of the press of the pressing unit 108. If users keep pulling the pulling portion 104 to have the handle member 34 keep moving along the X direction, the guiding plate 110 enters and slides along the second trough section 70 until the guiding plate 110 contacts the end of the second trough section 70. Then if the handle member 34 is forced to keep moving along the X direction, the tray bottom plate 38 is brought by the guiding plate 110 to move along the X direction since the guiding plate 110 has already been against the end of the second trough section 70. In other words, the hidden tray device 24 and the server module 14 as a whole can be pulled out along the positive X direction by users. If users need to push the hidden tray device 24 and the server module 14 as a whole in the accommodating space along the negative X direction, the handle member 34 can be pushed along the reverse direction according to the aforementioned description to have the guiding plates 110 enter the first trough sections 68. If users keep pushing the handle member 34 after the guiding plates 110 contact the end of the first trough sections 68, the tray bottom plate 38 is going to be brought by the guiding plates 110 to move along the negative X direction.

Then when the pressing unit 108 passes the engaging portion 80 along the negative X direction completely, the engaging portion 80 is going to fall in the engaging hole 50; as a result, the engaging portion 80, the hidden tray device 24, and the server module 14 are in the engaged state.

As shown in FIG. 9 and FIG. 10, when the engaging portion 80 of the hidden tray device 24 is in the engaged state, the pulling portion 104 is adjacent to the second surface 66 of the tray bottom plate 38. Concisely, the hidden tray device 24 is hidden in the server housing 12, and components of the hidden tray device 24 do not extend to the outside of the server housing 12. As a result, the server housing 12 occupies less space, and has a better appearance. In addition, a part of the pulling portion 104 extends from the receiving notch 52 of the housing bottom plate 22 so that users can conveniently hook the pulling portion 104 by fingers to pull the handle member 34 out. During the process that the handle member 34 is being pulled out by users, the pressing unit 108 can press the engaging portion 80, and the engaging portion 80 can be disengaged simultaneously; therefore, users need no extra operation to disengage the engaged state. Such that the instant disclosure is more convenient in terms of operation.

While the instant disclosure has been described by way of example and in terms of the preferred embodiments, it is to be understood that the instant disclosure needs not be limited to the disclosed embodiments. For anyone skilled in the art, various modifications and improvements within the spirit of the instant disclosure are covered under the scope of the instant disclosure. The covered scope of the instant disclosure is based on the appended claims.

1. A server housing comprising:
a housing bottom plate comprising an engaging hole; and
a hidden tray device comprising:
a tray bottom plate comprising a receiving opening, at least a guiding trough, a first surface, and a second surface opposite to the first surface, the receiving opening and the guiding trough penetrating through the tray bottom plate from the first surface to the second surface, the second surface being near the housing bottom plate;
a switch body comprising an engaging portion a first plate body, and a second plate body connected to the first plate body, one end of the first plate body of the switch body being fastened to the first surface of the tray bottom plate, the engaging portion protruding from another end of the second plate body of the switch body, the second plate body being bent with respect to the first plate body, the second plate body being biased toward the receiving opening, the engaging portion passing through the receiving opening and being in the engaging hole; and
a handle member comprising a handle body, at least a guiding portion, and a pressing unit, the guiding portion being connected to the handle body and slidably disposed in the guiding trough of the tray bottom plate, the handle body and the pressing unit being between the tray bottom plate and the housing bottom plate, wherein when the guiding portion slides in the guiding trough, the pressing unit is capable of pressing the engaging portion and having the engaging portion moved out of the engaging hole.

2. The server housing of claim 1, wherein the number of the guiding trough is two, the two guiding troughs are symmetrically disposed on two sides of the receiving opening, the number of the guiding portion is two, and the two guiding portions are symmetrically disposed on two sides of the handle body.

3. The server housing of claim 2, wherein the guiding portion comprises a guiding plate and a pressing plate, one end of the guiding plate is connected to the handle body, another end of the guiding plate is connected to the pressing plate, the guiding plate is in the guiding trough, and the pressing plate is against the first surface of the tray bottom plate.

4. The server housing of claim 3, wherein the guiding trough comprises a first trough section and a second trough section, a trough width of the first trough section is greater than that of the second trough section.

5. The server housing of claim 4, wherein a trough width of the second trough section is substantially equal to a thickness of the guiding plate.

6. The server housing of claim 1, wherein the handle body further comprises a receiving trough, the receiving trough penetrates through the handle body and is parallel with the guiding trough, the engaging portion passes through the receiving trough, and the pressing unit is at one end of the receiving trough.

7. (canceled)

8. The server housing of claim 1, wherein a side of the second plate body away from the first plate body is against the handle body.

9. The server housing of claim 1, wherein the tray bottom plate further comprises two fastening posts protruding from the first surface of the tray bottom plate, the switch body further comprises two fastening holes penetrating through the first plate body, and the two fastening posts respectively pass through the two fastening holes.

10. The server housing of claim 9, wherein the tray bottom plate further comprises a positioning post protruding from the first surface of the tray bottom plate, the switch body further comprises a positioning notch recessed from an edge of the first plate body away from the second plate body, and the positioning post is engaged to the positioning notch.

11. The server housing of claim 1, wherein the engaging portion comprises a steep face and a gradual face opposite to the steep face, the gradual face faces toward the pressing unit, the steep face is against an inner side of the engaging hole, and the pressing unit is capable of being against the gradual face and pressing the engaging portion to have the engaging portion moved out of the engaging hole.

12. The server housing of claim 1, wherein the handle body further comprises a convex structure, the tray bottom plate further comprises a concave structure, and the convex structure and the concave structure are contacted with each other for positioning.

13. The server housing of claim 1, wherein the housing bottom plate further comprises a receiving notch recessed from an edge of the housing bottom plate, the handle member further comprises a pulling portion connected to the handle body, being opposite to the pressing unit, and being near the second surface of the tray bottom plate, and at least a part of the pulling portion extends to outside the receiving notch.
